(19) United States
(12) Patent Application Publication
(10) Pub. No.: US 2011/0210757 A1
(43) Pub. Date: Sep. 1, 2011

(54) APPARATUS AND METHOD TO MEASURE PROPERTIES OF POROUS MEDIA

(75) Inventors: Alexander Bismarck, London (GB); Georffery Frederick Hewitt, Wallingford (GB); Karen Shu San Manley, Reading (GB)

(73) Assignee: Imperial Innovations Limited, London (GB)

(21) Appl. No.: 12/673,892

(22) PCT Filed: Aug. 14, 2008
(86) PCT No.: PCT/GB2008/002754

§ 371 Date: Feb. 17, 2010

(30) Foreign Application Priority Data
Aug. 17, 2007 (GB) 0716120.1

(51) Int. Cl. G01R 27/08

(52) U.S. Cl. 324/693

(57) ABSTRACT

A method to determine properties of a porous material, in which: a porous sample is prepared and sealed; first the sample is evacuated to near vacuum; then a non-wetting and electrically conducting fluid is passed through the sample at a known pressure and the volume of the fluid taken up by the sample is measured; then a small differential pressure is applied across the sample and the flow rate of the fluid through the sample is measured; and an alternating current is passed through the sample and the resistance across the sample is measured.

The present invention is directed towards a method and apparatus for the measurement of properties of porous media. In particular it is directed towards the relationship between pore structure and flow and diffusion in the porous medium.

Porous materials often contain pores that are interconnected thereby forming a network that allows fluid flow within the system. Understanding the pore size distribution and structure of this network is a very important step in understanding the characteristics of the flow through the porous medium. Similarly, the diffusion of species through the pores in the medium in the absence of flow is also affected (though in a different way) by the pore structure. There is therefore a need to understand in as much detail as possible not only the pore size within a material but also the pore structure.

Classically, the approach has been to make measurements of the permeability of the medium to a particular fluid (gas or liquid) and to measure the rate of species diffusion. Measurements have usually been made for the case where the medium is saturated with the gas or liquid—i.e. where there are no fluid interfaces in the medium. In such a case, the medium can be described as being saturated with the given fluid phase. However, these overall measurements do not give information about the link between pore structure and the fluid transport processes.

For many decades, attempts to forge this link have been made on the basis of data from porosimetry studies. Such data have been obtained by one of two main techniques:

(1) Mercury porosimetry in which the medium is first evacuated and is then surrounded by mercury. Pressurisation of the mercury leads to it penetrating the pores. The relationship between the diameter d of the smallest pore penetrated at a given applied pressure P is set out in Equation (1) below, (“A General Analysis for Mercury Porosimetry”, Powder Technology, vol. 33, p. 201, Smithwick, 1982).

$$d = \frac{- 4 γ cos θ}{P} \qquad ( 1 )$$

where γ is the surface tension and θ is the contact angle of mercury.

The data obtained is usually presented in terms of pore volume penetrated as a function of the pore diameter calculated from the above Equation 1.

(2) Measurements of the uptake of a wetting liquid. Here, the capillary pressure is measured and the pore size distribution estimated from the measurements as set out, for example, in U.S. Pat. No. 4,211,106.

However, there is a basic difficulty in using just porosimetry data to interpret permeability and diffusivity measurements of a porous material. In practice, the pores have a complex path through the medium with some of the penetrated pores having “dead ends” (and therefore play no part in fluid transport) and others containing throats which restrict the flow. There is therefore a need for a new method and apparatus to determine properties of a porous material with greater accuracy.

According to the present invention there is provided a method to determine properties of a porous material, in which: a porous sample is prepared and sealed: first the sample is evacuated to near vacuum; then a non-wetting and electrically conducting fluid is passed through the sample at a known pressure and the volume of said fluid taken up by the sample is measured; then a small differential pressure is applied across the sample and the flow rate of said fluid through the sample is measured; and an alternating current which can be varied is passed through the sample and the resistance across the sample is measured.

Optionally, the method is repeated at different applied pressures. Preferably the pressure is increased in small increments and measurements are taken at each new applied pressure until there is no further fluid penetration (i.e. an increase in pressure does not force any fluid to be taken up by the sample as the porous material is saturated). Preferably the non-wetting and electrically conducting fluid is mercury.

The invention also extends to apparatus for determining properties of a porous material, the apparatus comprising: a sample cell for holding a sample of the porous material; two measuring tubes open at the bottom end to opposite ends of the sample and also connected to sumps for a non-wetting and electrically conducting fluid, and open at the top end to a vacuum pump; means for applying a fixed pressure to the system; means for applying a differential pressure across the sample; means for applying a current across the sample and means for measuring the resistance across the sample.

A novel method has been developed and an apparatus designed and tested to measure the characteristics of a porous material by penetrating the medium with, for example, mercury at a series of pressures. The amount of mercury taken up by the medium at a given applied pressure gives a measurement of the pore size distribution following the widely-used principle of mercury porosimetry. Having reached an equilibrium mercury penetration at a given pressure, a differential pressure (small compared with the total applied pressure) is applied across the medium and the rate of mercury flow through the medium measured. This allows the determination of the permeability of the medium for those pores penetrated at the given applied pressure.

The permeability rises with pressure (i.e. with decreasing size of penetrated pores) and a plot of permeability against pressure (or pore volume penetrated) gives unique information about the mechanism of flow through the medium. At a high enough pressure, the mercury permeability becomes equal to the permeability for a wetting fluid (gas or liquid). The flow is likely to be dominated by flow in the larger interconnected pores so the total permeability may be reached with only a small fraction of the pore volume penetrated.

Also at any applied pressure, the electrical conductivity of the medium is determined. For an electrically non-conducting medium, the measured electrical conductivity is governed by the electrical conductance through the mercury and is analogous to the process of diffusion through the penetrated pores. For low pressures, the conductivity will be zero (assuming the medium itself is an electrical insulator) but, with increasing pressure, the conductivity through the penetrated pores increases and eventually reaches a constant value at high pressures. The variation of the electrical conductivity with pressure gives an indication (analogous to that for permeability in the mercury permeability tests) of the contributions of the various pores to diffusive transport through the medium.

As the applied pressure is increased, both the mercury permeability and the conductivity increase, eventually reaching the values for the saturated medium. The way in which permeability and conductivity vary with pressure, coupled with the information on the pore volume penetrated, gives new insights into the pore structure and behaviour in the medium.

It will be noted that the three sets of measurements (porosimetry, permeability and conductivity) may be combined to give unique insights into the pore structure and its relationship to flow and diffusion in the medium.

The present invention will be demonstrated with reference to the following figures, in which:

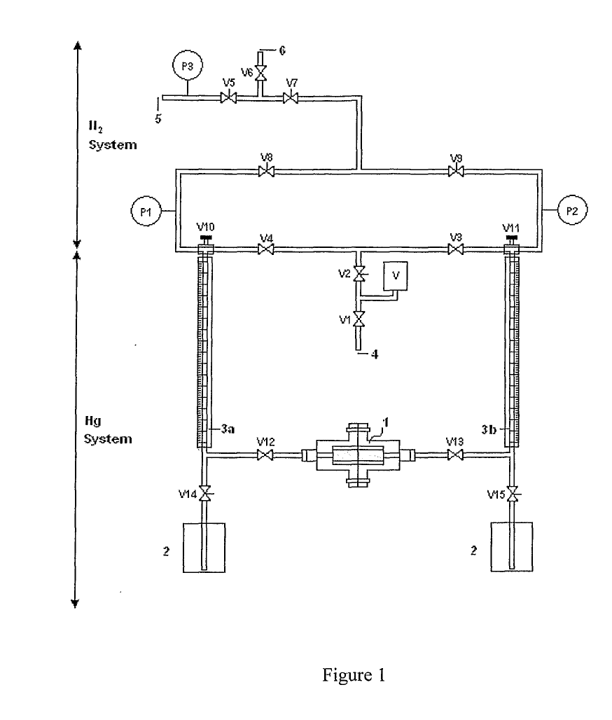

FIG. 1 shows schematically the apparatus for an embodiment of the invention;

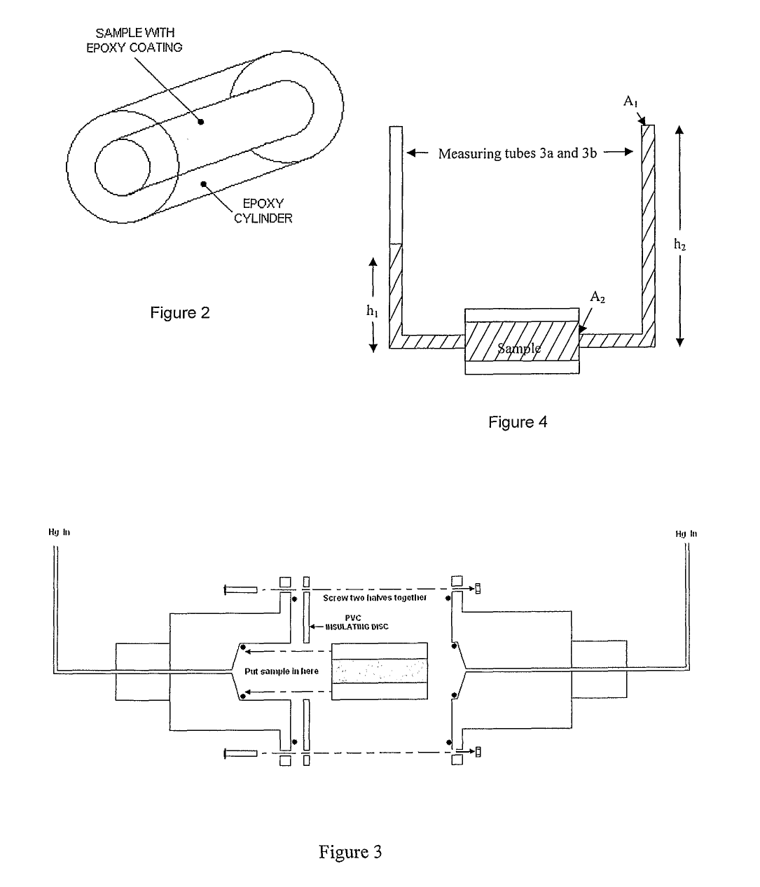

FIG. 2 shows an example of a sample prepared according to the present invention;

FIG. 3 shows in greater detail and example of a sample cell;

FIG. 4 shows schematically the sample and measuring tubes;

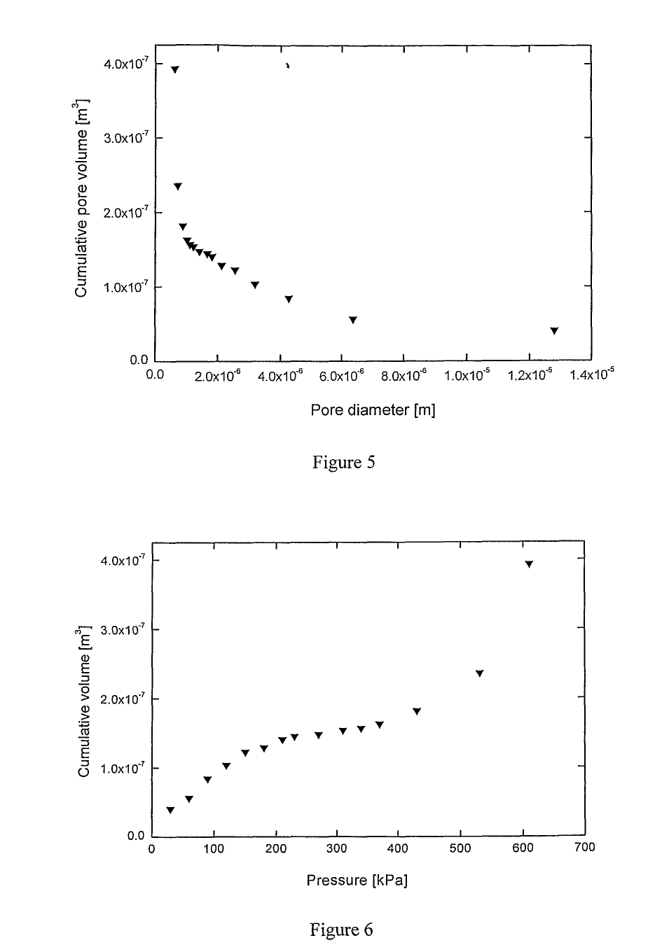

FIG. 5 is a graph showing the relationship between pore diameter and cumulative pore volume for a sandstone sample;

FIG. 6 is a graph showing the relationship between applied pressure and cumulative pore volume for a sandstone sample;

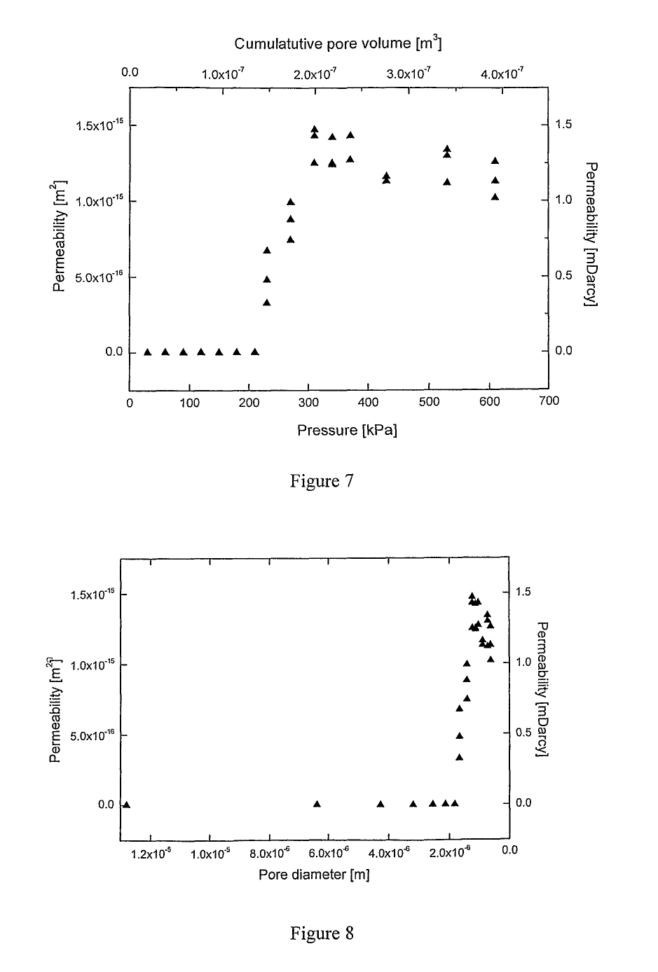

FIG. 7 is a graph showing the variation of permeability with applied pressure for a sandstone sample;

FIG. 8 is a graph showing the variation of permeability with pore diameter for a sandstone sample;

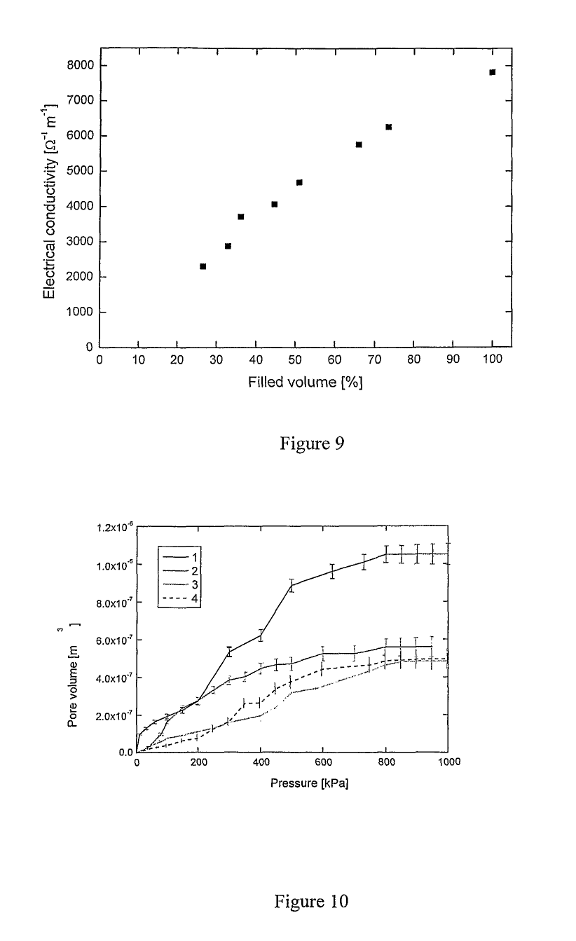

FIG. 9 is a graph showing the relationship between pore volume filled and electrical conductivity for a sandstone sample.

FIG. 10 is a graph showing the relationship between pore volume and applied pressure for four sandstone samples of different porosity;

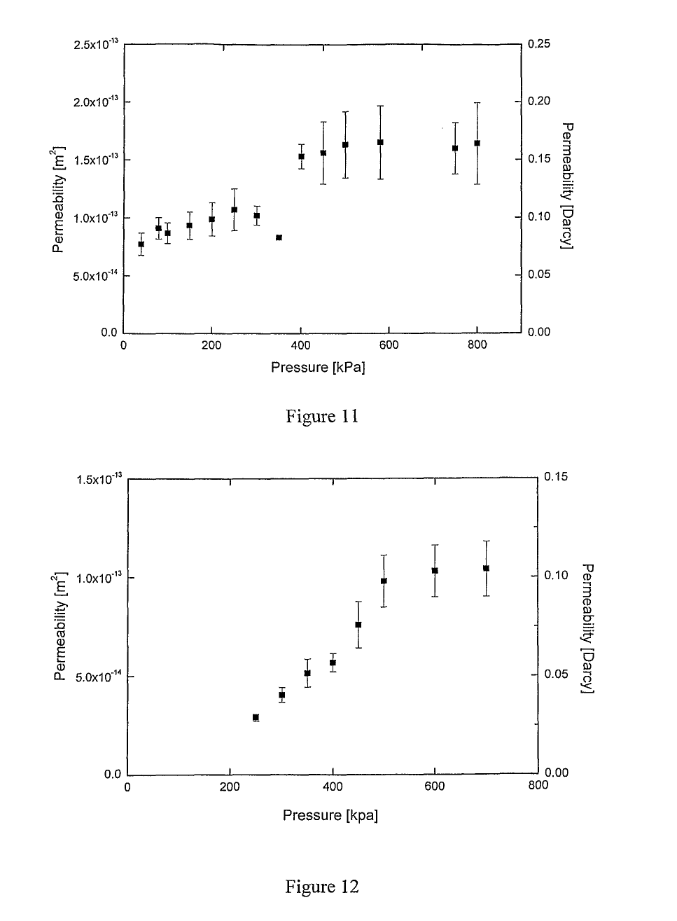

FIGS. 11 to 14 are graphs showing the relationship between permeability and applied pressure for each of samples 1 to 4 respectively; and

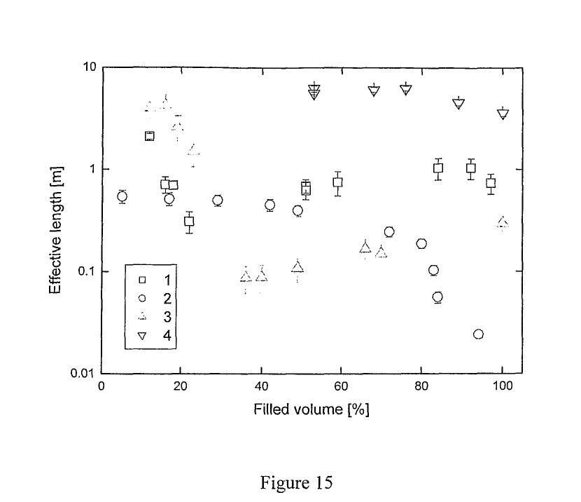

FIG. 15 shows the relationship between effective pore length and saturation for the four samples.

FIG. 1 shows schematically the apparatus for performing the method of the present invention. The apparatus may be divided into two main sections, the nitrogen system and the mercury system. In the apparatus of FIG. 1, the sample is placed into a cell (as shown in FIGS. 2 and 3 below). The sample cell 1 is placed in the middle of the mercury system between two mercury sumps 2. The cell is controlled by means of valves Vn. The mercury sumps 2 are directly connected to measuring tubes 3a, 3b which are also open to the ends of the sample cell 1. At the top end of the measuring tubes there is a vacuum pump 4 which is controlled by valves Vn and monitored by means of a Pirani Vacuum Gauge V and a series of valves Vn. The pressure on the respective sides of the system is measured by means of pressure gauges P1, P2.

In the nitrogen system, which is directly attached to the top of the measuring tubes 3a, 3b, there is a nitrogen inlet 5 connected to a nitrogen supply (not shown) and a nitrogen exhaust 6. Each of the supply and exhaust is controlled by means of a valve Vn.

### Preparation of Samples

To eliminate any fluid leakage around the edges of the sample and to ensure the sample is of the correct dimensions, the sample cores must be sealed with a non-permeable coating. This is achieved by first coating the whole surface of the sample with a layer of epoxy resin, for instance. When this has set, then the sample is set coaxially in an epoxy resin cylinder as shown in FIG. 2, using a PTFE sample mould. Once fully coated and sealed, the core must then be machined at either end to reveal the faces of the sample. The coated samples are sealed in a sample cell as shown in FIG. 3 and connected to the rig shown schematically in FIG. 1.

### Evacuation and Set Up

Before any mercury is allowed into the system, both the apparatus and the sample must be evacuated. A pressure of 10 Pa is sufficient, this can be monitored on a Pirani gauge V (see FIG. 1). By closing valve V1, the pump 4 is isolated and the pressure of the system can be monitored. Once at operating pressure, valves V10 and V11 are closed to prevent the flow of mercury to the nitrogen and the vacuum systems. Valves V10 and V11 are three-way valves and can be turned to give access to the nitrogen or the vacuum system or be completely closed.

At the initial condition, the sample and its associated system are under vacuum. Opening valves V14 and 15 allows mercury from the sumps 2 to rise to be in contact with the sample faces and to further rise up the PTFE measuring tubes 3a and 3b to identical heights in each tube. At this stage, the pressure of the mercury in contact with the sample faces corresponds to the static head of the mercury in tubes 3a and 3b and must be kept lower than the pressure required for mercury to penetrate into the largest pores of the sample. To prevent mercury from flowing back to the sump when pressurising the system, valves V14 and V15 are closed. Valves V3 and V4 are then closed and nitrogen gas is admitted to the nitrogen system through nitrogen inlet 5 when valves V5, V7, V8 and V9 are opened. The pressure in the nitrogen system is monitored on pressure gauges P1 and P2. A gas exhaust valve V6 is installed to allow the nitrogen pressure to be reduced if required.

### Porosimetry Measurements

Porosimetry involves measuring the mercury volume uptake by the sample as a function of the pressure applied at the interface between the bulk mercury and the sample faces. As was stated above, the initial value of this pressure corresponds to the static head applied by the mercury in tubes 3a and 3b, which must be low enough to avoid penetration of the largest pores in the sample.

The system must be evacuated and set up as described above and the heights of mercury in each of the measuring tubes (which should be identical) are recorded. To begin the penetration into the largest pores, nitrogen gas is applied to the system at a known pressure. The nitrogen pressure is controlled using the inlet valve V5, and if necessary can be lowered using the exhaust valve V6. Turning the three-way valves V10 and V11 to open the nitrogen side will admit nitrogen gas to the mercury system and apply pressure to the mercury in the measuring tubes. The gas will force mercury at the faces of the sample to begin to penetrate the larger pores. As indicated by Equation 1, the pores of equivalent size or larger than the diameter that corresponds to the applied pressure, will be penetrated with mercury. Once the system has equilibrated, the new heights in the measuring tubes are recorded.

The difference in the initial and final heights of mercury in the measuring tubes enables the deduction of the volume of mercury that has penetrated the pores at the applied pressure and hence, the total volume of the pores open to channels of the given diameter.

Increasing the nitrogen applied pressure by small increments, repeating the process of pore penetration and taking measurements of the mercury volume that has filled the sample pores will give a pore size distribution.

After each incremental pore volume measurement is made, permeability and conductivity measurements should be carried out before a pressure increase is introduced, see discussion below.

This procedure may be repeated until there is no further mercury penetration.

### Permeability Measurements

Once the pore volume has been determined at a known pressure using porosimetry measurements as described above, the mercury permeability can then be measured.

A differential pressure must be applied across the sample to induce mercury flow. This can be achieved by closing valve V8 and opening valve V6 briefly to reduce the pressure slightly in measuring tube 3a, and then closing valve V6. The pressure in measuring tube 3a can be adjusted by opening valve V8 as required, and similarly valve V9 can be used to adjust the pressure in measuring tube 3b as required. The pressure differential must, however, be small compared to the total pressure of the system.

To begin flow measurements, the heights in measuring tubes 3a and 3b at the initial condition, and hence the difference in heights, Δhₒ at time t=0 should be recorded.

The pressure in the nitrogen system should remain unchanged from the porosimetry measurements, and should not be notably affected by the small adjustments for the formation of the differential. The mercury will be forced through the sample in the direction of the pressure differential, to the low pressure side. Alternatively, the mercury heights can be reduced in measuring tubes 3a or 3b by opening then closing V14 or V15, respectively.

To measure the flow rate of mercury through the sample, the time taken for mercury to reach the final heights in the measuring tubes at time, t=t should be measured. The new mercury heights in tubes 3a and 3b and hence ΔHₜ should be recorded before V10 and V11 are turned to the off position.

This procedure can be repeated.

It is then possible to calculate the mercury permeability using equation (2) below when the difference in heights of mercury in the measuring tubes at t=0 and t=t and t are known. The rate at which mercury flows through the sample is characteristic of the permeability of the pore space containing mercury and is dependent on the applied pressure since it directly affects the pore space filled.

Referring to FIG. 4, the mercury permeability can be calculated as follows:

$$\frac{d ( Δ h )}{d t} = \frac{d ( {h}_{1} - {h}_{2} )}{d t}$$

$$d {h}_{1} = d {h}_{2} = \frac{- d V}{{A}_{1}}$$

$$and$$

$$d ( {h}_{1} - {h}_{2} ) = - 2 \frac{d V}{{A}_{1}} \\ \frac{d V}{d t} = \frac{{A}_{1} d ( {h}_{1} - {h}_{2} )}{2 d t} = \frac{{A}_{1} d ( Δ h )}{2 d t}$$

Applying Darcy's Law:

$$\frac{d V}{d t} = u {A}_{2} = \frac{{A}_{2} k Δ P}{μ L} \\ and \\ Δ P = ρ g Δ h \\ \frac{d V}{d t} = \frac{{A}_{2} k ρ g Δ h}{μ L} \\ \frac{{A}_{1} d ( Δ h )}{2 d t} = \frac{{A}_{2} k ρ g Δ h}{μ L} \\ k = \frac{d ( Δ h )}{2 d t} \frac{{A}_{1}}{2 {A}_{2}} \frac{μ L}{ρ g Δ h} \\ k = \frac{log Δ {h}_{0} / Δ {h}_{t}}{t} \frac{{A}_{1}}{2 {A}_{2}} \frac{μ L}{ρ g} \qquad ( 2 )$$

where k is the permeability of the sample, Δh is the difference in height between tubes 3a and 3b, t is the time taken to reach the final heights, A₁ is the cross sectional area of the manometer tubes A₂ is the cross sectional area of the sample, μ is the viscosity of mercury, ρ is the density of mercury, L is the length of the sample, g is the acceleration due to gravity.

The volume of mercury in the sample can then be increased as the porosimetry technique is continued and both pore size and permeability can be measured at higher nitrogen pressures. Repetition of this technique over a range of nitrogen pressures can lead to the determination of a pore size and permeability distribution.

### Electrical Conductivity Measurements

For gaseous diffusion of species A in species B in a porous medium, we may define a diffusivity ratio J which is the ratio of the diffusion coefficient measured for the porous medium (D) to the free gas diffusion coefficient D_{AB}. If the medium is itself non-conducting and if the electrical conductivity of the medium saturated by mercury is σ_{A}, then the ratio σ_{A}/σ_{T} (where σ_{T} is the conductivity of the mercury itself) would be expected to be identical to the diffusivity ratio J, since the processes of conduction and diffusion are analogous. The value (σ) measured of the electrical conductivity in the apparatus for a medium not saturated with mercury will be a function of the applied pressure, the value eventually reaching σ_{A} at high pressure. Thus, the variation of σ with pressure can give information about the contributions of pores of various sizes to the diffusivity. This is analogous to the similar information given by the mercury permeability measurements and the combination of the two measurements provides valuable information about the pore structure.

### Summary of the Procedure

The method of the present invention requires that once the porous sample has been coated, prepared and sealed in the sample cell, the apparatus and sample must be evacuated to a pressure in the range of 10 Pa. Mercury is then allowed to flood the mercury system of the apparatus, coming into contact with the sample faces and filling the measuring tubes. A first porosimetry measurement should be completed followed by the application of a small pressure gradient and then mercury flow measurements to determine the permeability that corresponds to the pore diameter deduced from the porosimetry. Measurements of the electrical resistance when an electrical alternating current is applied across the mercury in the sample should then be made. When completed, the nitrogen pressure should be increased by a small increment and the porosimetry, permeability and conductivity measurements repeated. The procedure should be carried out until the accessible pore volume has become fully saturated with mercury.

### EXAMPLE 1

A first example of the method of the present invention showing how the pore size distribution, permeability and tortuosity of a sandstone sample are measured and calculated is given below. A list of the physical constants is given in table 1 below.

TABLE 1

| Constant | Parameter | Value | Units |
|---|---|---|---|
| γ | Hg surface tension | 0.484 | Nm⁻¹ |
| θ | Hg contact angle | 140 | ° |
| D | Sample Diameter | 0.0130 | m |
| A₁ | Cross-sectional area of tubes | 3.14 × 10⁻⁶ | m² |
| A₂ | Cross-sectional area of sample | 1.33 × 10⁻⁴ | m² |
| μ | Hg viscosity | 1.55 × 10⁻³ | Pa · s |
| L | Sample length | 0.0250 | m |
| ρ | Hg density | 1.35 × 10⁴ | kg m⁻³ |
| g | Acceleration due to gravity | 9.81 | m s⁻² |
| σ_{T} | Hg electrical conductivity | 1.04 × 10⁶ | Ω⁻¹ m⁻¹ |

### Pore Size Distribution

Equation (1) is used to calculate the pore diameter d that corresponds to the applied pressure. The cumulative pore volume is measured experimentally by noting at each variation of applied pressure, the change in height and hence volume of mercury in the sample. FIG. 5 shows the cumulative volume of the pores at varying pore diameters and FIG. 6 shows the variation with applied pressure.

The cumulative pore volume can be used to deduce that the sample of sandstone used in this example has a total pore volume of 3.93×10⁻⁷ m³ which, since the sample volume is known, represents a porosity of 12%.

### Permeability Distribution

At each incremental pressure applied the rate of flow of mercury through the sample was measured. Experimentally measured parameters were the height of mercury in the measuring tubes at time t=0, t=t and the time t taken for the change to occur. Equation (2) was used to determine the permeability k. The variation of the permeability with the applied pressure is illustrated graphically in FIG. 7.

At low pressures there was no flow through the sample since the mercury had not penetrated any interconnecting pores. As the pressure was increased to around 250000 Pa, (1.53 μm pore diameter equivalent) the onset of mercury flow through the sample is evident. The permeability due to flow through pores of 1.25 μm diameter and above is approximately 0.3 mDarcy's (3×10⁻¹⁶ M²). As the pore diameter of saturated pores becomes smaller, the permeability of the porous system increases to 1.2 mDarcy's (1.2×10⁻¹⁵ m²). When the applied pressure reaches 320000 Pa (1.23 μm pore diameter) there is no longer a notable increase in the permeability. This indicates that pores smaller than 1.23 μm do not contribute to flow. FIG. 8 shows the contribution to flow of pores of various pore diameters.

### Conductivity

The electric resistance R across the sample was measured and the conductivity σ calculated from the equation:

σ=L/(AR)

where A is the cross sectional area of the sample and L is the sample length. At high pressures, σ approaches σ_{A}.

Using the apparatus and method of the present invention it is possible to measure and calculate properties of a porous material and in particular to understand the pore structure of the material and the relationship to flow and diffusion properties through the medium.

### EXAMPLES 2-5

These examples further exemplify the present invention by reference to sandstone samples 1-4. The four samples have different porosities as set out in table 2 below.

TABLE 2

| Sample | Porosity [%] |
|---|---|
| 1 | 30.26 ± 0.67 |
| 2 | 22.13 ± 1.11 |
| 3 | 6.98 ± 0.38 |
| 4 | 5.27 ± 1.12 |

FIG. 10 shows the volume of the pores that were penetrated with mercury for each of samples 1 to 4 at various applied pressures. When very low pressures were applied, small volumes of mercury were pushed into the larger pores of the samples and as the applied pressure was increased, the volume of mercury in the pores was increased. The permeability of Sample 1 reaches a maximum of 1.64×10⁻¹³ m² (164 mD) and the permeability distribution is shown in FIG. 11. The maximum permeability is reached at around 400 kPa, which corresponds to a pore diameter of 0.957 μm, indicating there was no mercury flow through pores with larger diameters than this. FIG. 1 shows that at pressures higher than 400 kPa, the pore volume increases from 6.5×10⁻⁷ m³ to 1.01×10⁻⁶ m³ but since there was no significant increase in permeability as this volume was filled, it can be concluded that the effective pore volume is 6.5×10⁻⁷ m³. The effective porosity was then calculated to as 0.205 since the volume of the sample was known. The term “effective” porosity denotes the porosity that is interconnected and through which fluid can flow. The total porosity includes the dead end pores and edge pores which fluid cannot flow through to the other side of the material but can still be classified as pore volume.

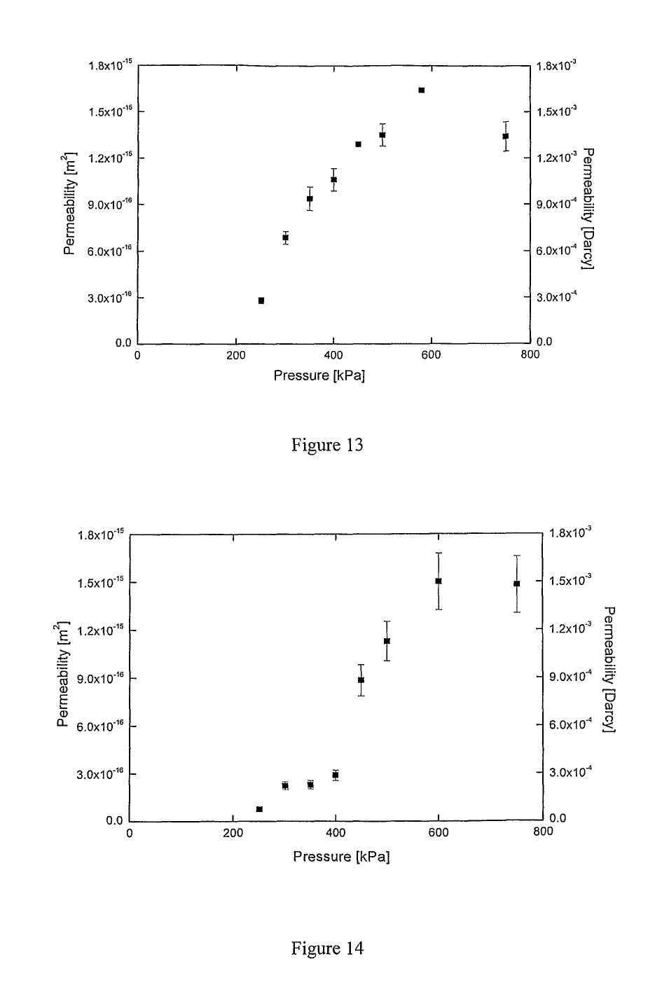

The pore volume of Sample 2 was 5.25×10⁻⁷ m³. The permeability results shown in FIG. 12 indicate that until a pressure of 250 kPa was applied there is no flow through the material. At 250 kPa, pores with a diameter of 1.53 μm were filled with mercury and this was the flow limiting pore diameter. At around 600 kPa, the permeability was 1.04×10⁻¹³ m² (104 mD) the maximum permeability reached. FIG. 10 shows that there is no further pore penetration at pressures higher than 600 kPa so for Sample 2, all of the pore volume contributes to the fluid flow. The total pore volume of Sample 3 is 4.84×10⁻⁷ m³. FIG. 13 and FIG. 14 shows the permeability distribution for Sample 3 and Sample 4 respectively. The total permeability of Sample 3 is 1.34×10⁻¹⁵ m² (1.34 mD) and is reached at approximately 500 kPa. Since there is still mercury penetration into the pores at pressure greater than 500 kPa we can deduce that total porosity does not contribute to the flow. The total permeability of Sample 4 is 1.48×10⁻¹⁵ (1.48 mD).

Table 3 summarises the results obtained for the sandstone samples in this investigation.

TABLE 3

| | | Porosity | | Limiting Pore | Effective | |
|---|---|---|---|---|---|---|
| Sample | Pore Volume [m³] | [%] | k [mD] | Throat Diameter [m] | Length [m] | σ/σₜ |
| 1 | 1.01 × 10⁻⁶ ± 1.50 × 10⁻⁷ | 0.30 ± 0.05 | 164 ± 17.62 | 3.83 × 10⁻⁵ ± 1.28 × 10⁻⁵ | 0.73 ± 0.57 | 0.0104 ± 0.0294 |
| 2 | 5.25 × 10⁻⁷ ± 4.10 × 10⁻⁸ | 0.16 ± 0.01 | 104 ± 13.92 | 1.53 × 10⁻⁶ ± 3.00 × 10⁻⁸ | 0.12 ± 0.01 | 0.0071 ± 0.0005 |
| 3 | 4.84 × 10⁻⁷ ± 2.51 × 10⁻⁸ | 0.15 ± 0.01 | 1.34 ± 0.01 | 9.57 × 10⁻⁶ ± 1.06 × 10⁻⁶ | 0.30 ± 0.03 | 0.0123 ± 0.0006 |
| 4 | 4.96 × 10⁻⁷ ± 9.74 × 10⁻⁸ | 0.15 ± 0.03 | 1.48 ± 0.18 | 1.53 × 10⁻⁵ ± 3.00 × 10⁻⁸ | 3.56 ± 0.51 | 0.0010 ± 0.0001 |

FIG. 15 shows the variation of the effective pore length with the percentage saturation of Samples 1 to 4. The effective pore length of Sample 1 is high at small pore volumes showing that the pores are extremely tortuous, with an increase in the pore volume filled, the electrical resistance was reduced and the conductivity of the mercury in the sample increased. The pore length is defined from the tortuosity and at maximum pore saturation was 0.7348 m. This length is high compared to the actual length of the sample and this indicates that none of the interconnecting pores reach from end to end of the sample, there is a complex route which the mercury must take but since the effective pore volume is low, there may be a low frequency of pores which allow fluid flow.

The effective pore length of Sample 2 at low pore volumes is approximately 0.5 m and drops to 0.1242 m when the total pore volume is filled. The effective pore length of Sample 3 is 0.296 m. Electrical conductivity measurements indicate that the total effective pore length of Sample 4 is 3.56 m which is extremely high compared to the measurements taken of Samples 1 to 3.50% of the total volume of the sample is filled with pores of diameters less than 1.53 μm and the pores that are larger have a very low permeability (0.3 mD), the very large effective pore length would explain why the overall flow rate at low mercury volumes is low. As the volume of mercury in the sample is increased, more and more small pores are filled and they do not necessarily connect the large pores.

1. A method to determine properties of a porous material, in which: a porous sample is prepared and sealed; first the sample is evacuated to near vacuum; then a non-wetting and electrically conducting fluid is passed through the sample at a known pressure and the volume of said fluid taken up by the sample is measured; then a small differential pressure is applied across the sample and the flow rate of said fluid through the sample is measured; and an alternating current (which can be varied) is passed through the sample and the resistance across the sample is measured.

2. A method as claimed in claim 1, in which the method is repeated at a number of different applied pressures.

3. A method as claimed in claim 2, in which the applied pressure is increased in small increments.

4. A method as claimed in claim 1, in which the fluid is mercury.

5. A method as claimed in claim 1, in which the permeability of the sample at an applied pressure is calculated from the flow rate of the fluid through the sample using equation (2)
$$k = \frac{log Δ {h}_{0} / Δ {h}_{t}}{t} \frac{{A}_{1}}{2 {A}_{2}} \frac{μ L}{ρ g} \qquad ( 2 )$$
where k is the permeability of the sample (m²), Δh is the difference in height between tubes 3a and 3b (m), t is the time taken to reach the final heights (s), A₁ is the cross sectional area of the manometer tubes (m²), A₂ is the cross sectional area of the sample (m²), μ is the viscosity of the fluid (Pa·s), ρ is the density of the fluid (kg in⁻³), L is the length of the sample (m), and g is the acceleration due to gravity (m s⁻²).

6. Apparatus for determining properties of a porous material, the apparatus comprising: a sample cell for holding a sample of the porous material; two measuring tubes open at the bottom end to opposite ends of the sample and also connected to sumps for a non-wetting and electrically conducting fluid, and open at the top end to a vacuum pump; means for applying a fixed pressure to the system; means for applying a differential pressure across the sample; means for applying a current across the sample; and means for measuring the resistance across the sample.
